(19) United States
(12) Patent Application Publication
(10) Pub. No.: US 2012/0132366 A1
(43) Pub. Date: May 31, 2012

(54) PLASMA PROCESSING APPARATUS

(75) Inventors: Pei-Shan Wu, New Taipei City (TW); Fu-Ching Tung, Hsinchu City (TW); Jung-Chen Ho, Hsinchu City (TW); Tean-Mu Shen, Hsinchu City (TW); Chia-Ming Chen, Changhua County (TW)

(73) Assignee: Industrial Technology Research Institute, Hsinchu (TW)

(21) Appl. No.: 13/157,878

(22) Filed: Jun. 10, 2011

(30) Foreign Application Priority Data
Nov. 25, 2010 (TW) 099140765

(51) Int. Cl. C23F 1/08; C23C 16/50; C23C 16/455

(52) U.S. Cl. 156/345.33; 156/345.44; 118/723 E

(57) ABSTRACT

A plasma processing apparatus is disclosed, which includes: a cathode module comprising a plurality of first channels which generate plasma; an anode having a chamber which contains the cathode and having at least one plasma outlet corresponding to the first channels; an electrode connected to a high-frequency electrical power and the cathode; and a plurality of second channels penetrating through the anode; wherein each first channel and each second channel are disposed alternately. A first gas is introduced into the first channels ionized under high frequency electrical power. In the first channels, the free electrons collided brings high density of plasma. The generated plasma is expelled through the plasma outlet to form a plasma diffusion region. A second gas is introduced into the plasma diffusion region through the second channels to take part in the reaction of plasma.

### TECHNICAL FIELD

The present disclosure relates to a plasma processing apparatus.

### TECHNICAL BACKGROUND

Plasma enhanced chemical vapor deposition (PECVD) is a process used to deposit thin films. Neutral gases flow into the reactor and are decomposed by collisions with energetic electrons in the plasma. Since most of the molecules of neutral gases are in the excited states, the traditional reaction operated at a high temperature can be processed at a lower temperature; and meantime, the energetic electrons in the plasma bump the deposited film resulting in a void-free and fully dense film.

A capacitively coupled plasma (CCP) is one of the most common types of industrial plasma sources. Two metal electrodes are separated by a small distance, placed in a reactor to form an electrical field to accelerate the electrons in the reaction chamber. The accelerated electrons bump the neutral gas molecules to cause ionization thereof and generate more and more ions and electrons to form the plasma. However, the accelerated electrons are also caused due to the effect of ion bombardment and thus damage the film deposited on the substrate.

Remote plasma processing is commonly understood as a technique which separates a primary plasma region spatially from the processing area to avoid the effect of ion bombardment and thermal load. One of the remote plasma processing apparatuses is the hollow cathode discharge (HCD). Please refer to FIG. 1, which shows a conventional HCD apparatus 400, composed of an anode 401 receiving a cathode 402. The cathode 402 is connected to a high frequency electrical power 403 with an output frequency such as 13.56 MHz. An insulator 404 formed of aluminum oxide (Al₂O₃) is used to separate the anode 401 and the cathode 402. The reacting gas, such as Ar, He, N₂, or H₂, is introduced into the cathode 402 via an insulating gas supplying means penetrating through the anode 401, and then is activated by the high-frequency electrical power. Due to the limitation of the cathode's 402 geometry, high energy electrons oscillate between repelling potentials of the sheaths at opposite walls in the cathode 402. Electrons are emitted from the cathode's 402 wall and accelerated by the electric field across the sheath. Electrons can undergo several inelastic collisions with the reacting gas along their paths to enhance ionization. The high density plasma jet is generated and then flown into the vacuum chamber 408 by the openings 406 and 407 of the anode 401 and the cathode 402 to form a plasma diffusion region 409. The plasma therein is applied to process the surface processing, film deposition, etching, and so on.

To apply the plasma to large area applications, the foregoing point plasma processing apparatus can be improved to a linear source or a planar source of plasma. Conventionally, the HCD apparatus with multiple discrete hollow cathode chambers for introducing each plasma jet is arranged horizontally expanding into the vacuum chamber. For the film deposition applications, the generated plasma excites the neutral gases to form a uniform plasma diffusion region and then deposit the film on a substrate.

FIG. 2 shows a vertical sectional view of a plasma processing apparatus disclosed in JP2003141045. The plasma processing apparatus has a plasma gas supplying means 158 and a non-plasma gas supplying means 160. The plasma gas supplying means 158 is provided with the reacting gas, such as Ar, He, N₂, or H₂, to be converted into plasma. The non-plasma gas supplying means 160 is used to provide the non-plasma gas to form the film. The plasma gas supplying means 158 and non-plasma gas supplying means 160 are disposed on one side of the processing vessel 132, which has plural plasma gas jetting holes 162A and plural non-plasma gas jetting holes 164A arranged at predetermined internals along the longitudinal direction of the processing vessel 132. The plasma gas supplying means 158 is disposed in a region surrounded by a pair of electrodes 176, while the non-plasma gas supplying means 160 is disposed in a region outside a pair of electrodes 176. A rotating table 144 is disposed in the processing vessel 132 with a holder 140A supporting plural working pieces W. The plasma gas jetting holes 162A and non-plasma gas jetting holes 164A are directed to the working pieces W, which are rotated by the rotating table 144. The plasma gas is jetted from the plasma gas jetting holes 162A and into the region surrounded by a pair of electrodes 176 to be ionized into plasma. The plasma is jetted towards the working pieces W. Meantime, the non-plasma gas is jetted from the non-plasma gas jetting holes 164A and towards the working pieces W, and decomposed or activated by the plasma to deposit on the working pieces W. However, the plasma processing apparatus is not suitable for applications of large-area deposition due the disturbance of the plasma gas and non-plasma gas.

FIG. 3 shows a side view of a cathode discharge apparatus disclosed in the Taiwan patent application TW201021078. The cathode discharge apparatus 210A includes an anode 211, a cathode 221, and plural cathode chambers 225. The cathode 221 is disposed inside the anode 211 separated by an insulator 222. The cathode 221 comprises plural cathode chambers 225 and can be divided into a first part of the cathode 221 a and a second part of the cathode 221b. Each cathode chamber 225 is composed of a first part of the cathode chambers 225a in the first part of the cathode 221a and a second part of the cathode chambers 225b in the second part of the cathode 221b. The first part of the cathode 221a includes a first gas channel 223a, a second gas channel 223b, an flow channel hole 223c, the first part of the cathode chamber 225a, and a chamber inlet 227a. The chamber outlet 227b is located at the bottom of the second part of the cathode chambers 225b inside the cathode 221. The cathode discharge apparatus 210A also includes electrical feedthroughs 241a and 241b, sockets 244a-f for the electrical feedthroughs, and an electrode connector 242. A plasma gas is introduced through the gas inlets 224a and 224b into the first gas channel 223a, through the flow channel hole 223c into the second gas channel 223b, and then by the chamber inlet 227a into the cathode chambers 225. The plasma gas 226 is activated and accelerated in the cathode chambers 225 to generate plasma, which is jetted out by the chamber outlet 227b. When the plasma gas 226 is about to saturate in the first gas channel 223a, it flows through the flow channel hole 223c into the second gas channel 223b. Due to the distribution of the plural flow channel holes 223c, the gas pressure along the second gas channel 223b is uniform. Thus, the apparatus is suitable for the applications of large-area film deposition. Also, please refer to FIG. 4, which shows another structure of the cathode discharge apparatus 300, including an anode 310 and two corresponding cathodes 322a and 322b. The tube-shaped cathodes 322a and 322b are disposed in parallel and in the anode 310. Each of the cathodes 322a and 322b has a respective electrical feedthroughs 341a and 341b. The cathode discharge apparatus 300 may have an electrode connector 342 and a power supplier 343 connected to the electrode connector 342. An external electric power is provided to the cathodes 322a and 322b by the electrode connector 342 and the electrical feedthroughs 341a and 341b. The electrical feedthroughs 341a and 341b are disposed at the opposite two terminals of the two cathodes 322a and 322b to balance the flowing electric current, so as to distribute the plasma more uniformly, especially for the large-area film deposition.

Accordingly, an issue facing the industrial sector and calling for urgent solution is to develop a plasma processing apparatus that facilitates scale-up in axial and radial. High plasma density and uniform distribution of the ionization are provided to reduce the production cost.

### TECHNICAL SUMMARY

According to one aspect of the present disclosure, one embodiment provides a plasma processing apparatus, which includes: a cathode module comprising plural first channels which generate plasma; an anode having a chamber which contains the cathode and having at least one plasma outlet corresponding to the first channels; an electrode connected to a high-frequency electrical power and the cathode; and plural second channels penetrating through the anode; wherein each first channel and each second channel are disposed alternately.

A first gas is introduced into the first channels ionized under high frequency electrical power. In the first channels, the free electrons collided brings high density of plasma. The generated plasma is expelled through the plasma outlet to form a plasma diffusion region. A second gas is introduced into the plasma diffusion region through the second channels to take part in the reaction of plasma. Also, insulators are interposed between the cathode module and the anode, between the first channels and the anode, and between the electrode and the anode, to assure positive and negative electricity separation thereof.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 shows a conventional plasma generating apparatus.

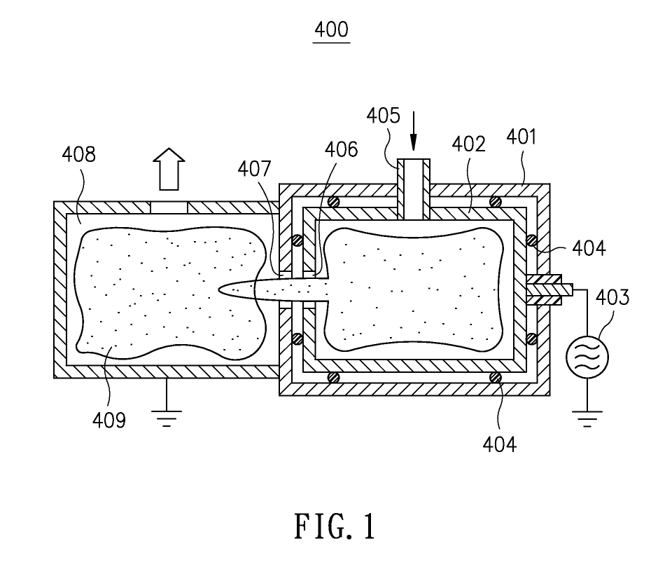

FIG. 2 is a vertical sectional view of a plasma processing apparatus disclosed in JP2003141045.

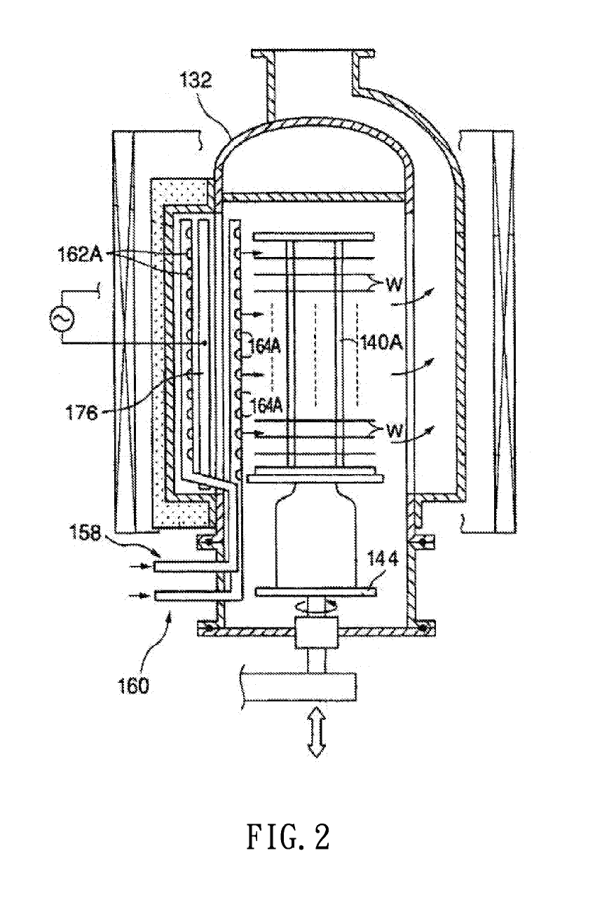

FIG. 3 is a side view of a cathode discharge apparatus disclosed in the Taiwan patent application TW201021078.

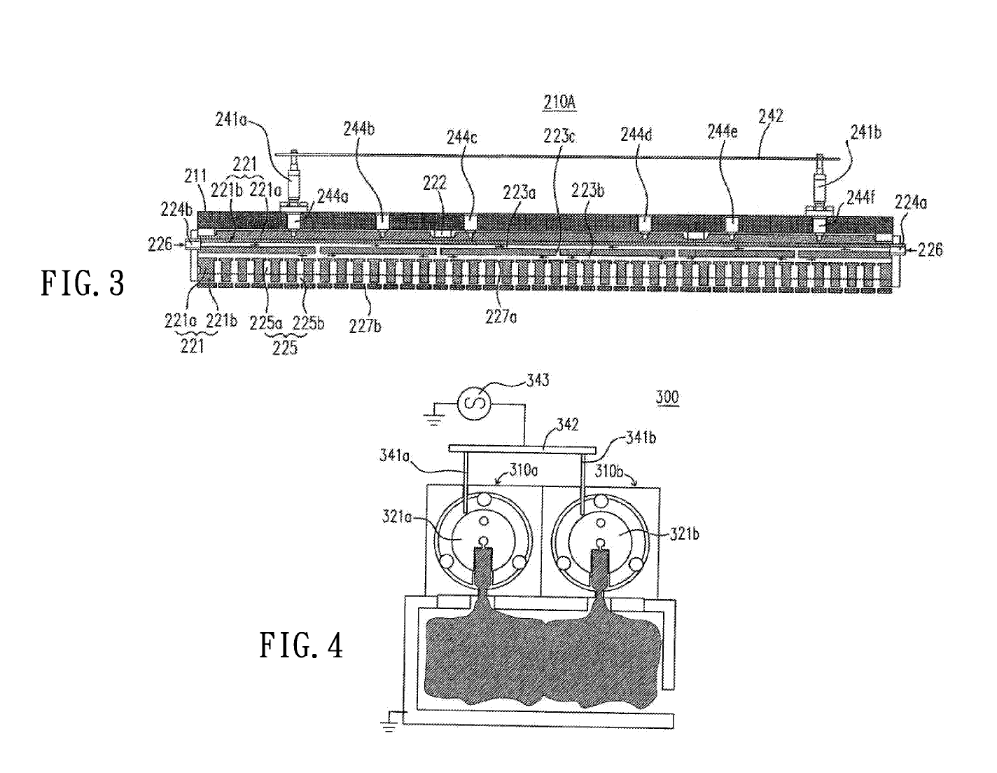

FIG. 4 is another structure of the cathode discharge apparatus disclosed in the Taiwan patent application TW201021078.

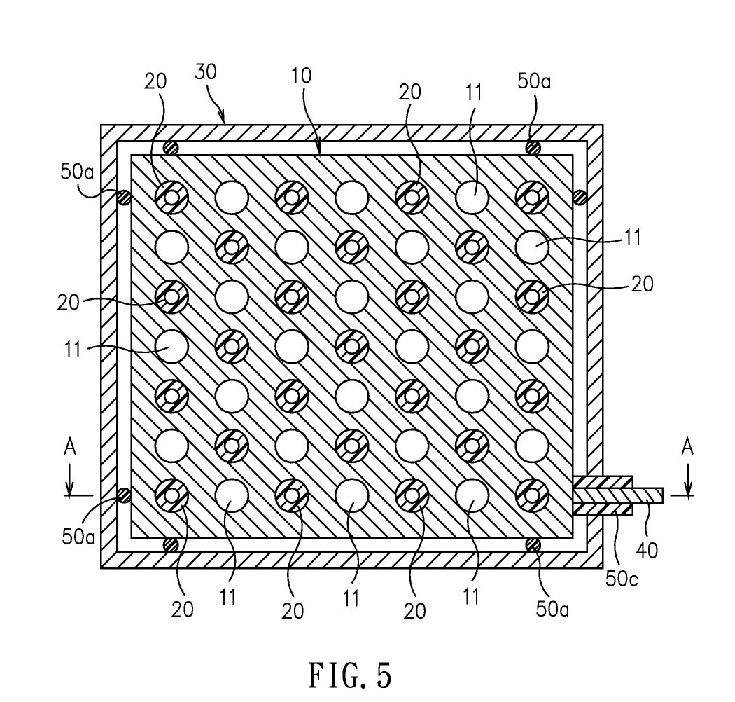

FIG. 5 is a bottom view of a plasma processing apparatus according to an embodiment of the present disclosure.

FIG. 6 is a cross-sectional view taken along a line A-A′ of FIG. 5.

FIGS. 7 and 8 are bottom views of the plasma processing apparatus according to another two embodiments of the present disclosure.

FIGS. 9 to 12 are the embodiments with various designs of the plasma outlet.

FIGS. 13 to 16 are the embodiments of the ranked structure in the second channels.

### DESCRIPTION OF THE EXEMPLARY EMBODIMENTS

For further understanding and recognizing the fulfilled functions and structural characteristics of the disclosure, several exemplary embodiments cooperating with detailed description are presented as the following.

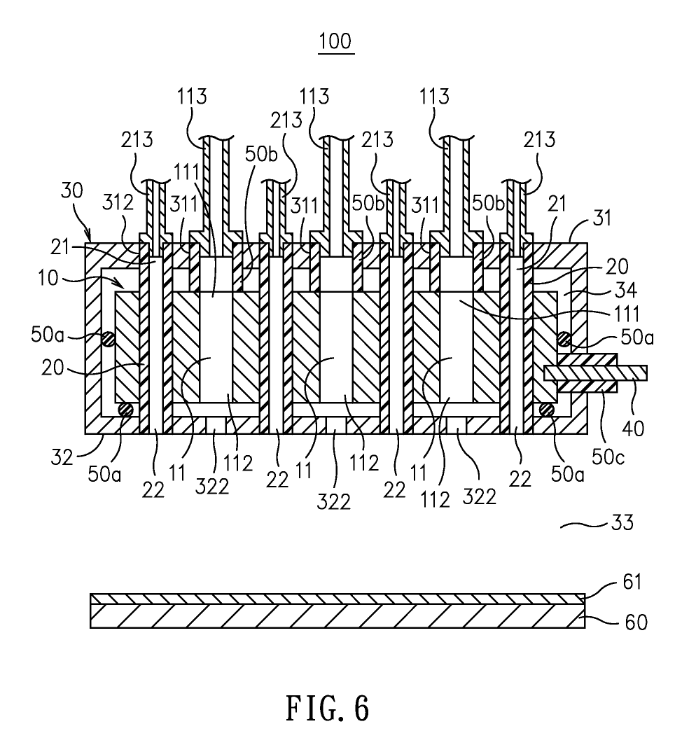

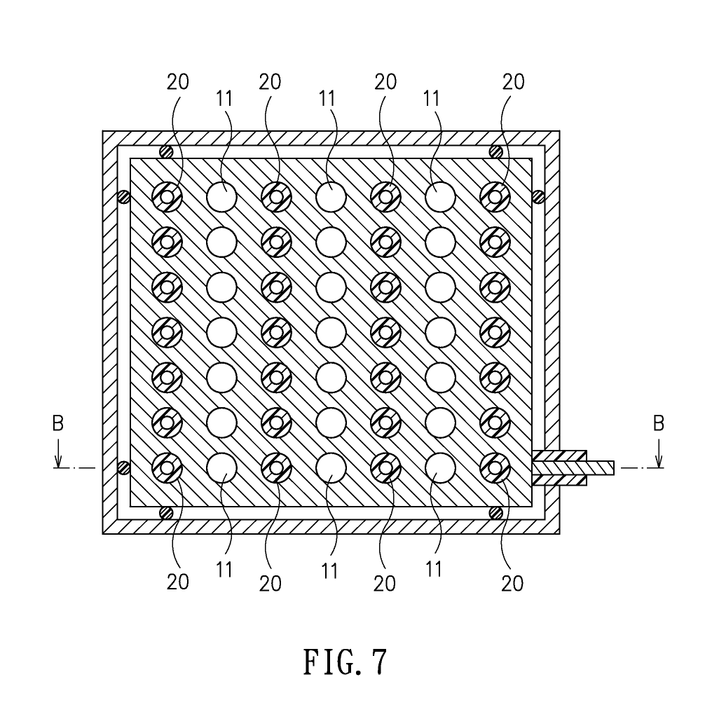

Please refer to FIGS. 5 and 6. FIG. 5 shows a bottom view of a plasma processing apparatus according to an embodiment of the present disclosure. FIG. 6 is a cross-sectional view taken along a line A-A′ of FIG. 5. The plasma processing apparatus 100 comprises a cathode module 10, a plurality of second channels 20, an anode 30, an electrode 40, and a plurality of insulators 50a, 50b, and 50c.

The anode 30 comprises a chamber 34 which can contain the cathode module 10. An object 60 to be plasma-processed is disposed under the bottom 32 of the anode 30 by a predetermined distance.

The electrode 40 penetrates through the anode 30 and connects with the cathode module 10, wherein the insulator 50c is used to electrically separate the electrode 40 from the anode 30. A high-frequency electrical power (not shown) is supplied to the cathode module 10 via the electrode 40. The cathode module 10 comprises a plurality of first channels 11, and each first channel 11 has a first inlet 111 and a first outlet 112. A plasma outlet 322, corresponding to each first outlet 112, is formed in the bottom 32 of the anode 30. A first gas supplying means 113 is connected to the first inlet 111, so that the first gas supplying means 113 can communicate with the plasma outlet 322 through the first channel 11.

The second channels 20 penetrate through the anode 30 and the cathode module 10. Each second channel 20 has a second inlet 21 and a second outlet 22. A second gas supplying means 213 is connected to the second inlet 21, so that the second gas supplying means 213 can communicate with the second outlet 22 through the second channel 20. Each first channel 11 and each second channel 20 are disposed alternately.

In the embodiment, the insulators 50a are interposed between the cathode module 10 and the anode 30, the insulators 50b are interposed between the first gas supplying means 113 and the anode 30, the insulators 50c are interposed between the electrode 40 and the anode 30, and the second channels 20 are formed of insulating material. If the second channels are formed of non-insulating material, insulators can be interposed between the second channels 20 and the cathode module 10 and the anode 30.

A first gas provided into the first channels 11 via the first gas supplying means 113 to participate in the plasma processing. The first gas can be argon (Ar), helium (He), nitrogen (N₂), hydrogen (H₂), and/or the other gas which can not react with the foregoing gases chemically to avoid the aggregation in the first channels 11. The first gas can be excited by the high-frequency electrical power to generate the plasma. The generated plasma flows out of the first channels 11 via the first outlets 112 into the plasma outlet 322, and forms a plasma diffusion region 33 between the object 60 and the bottom 32 of the anode 30.

Meantime, a second gas is provided into the second gas supplying means 213. In the embodiment, the selection of the second gas is based on film deposition. For example, the second gas may be selected as the mixture of oxygen (O₂) and silane (SiH₄) for depositing a silicon oxide (SiOₓ) film, the mixture of ammonia (NH₃) and silane for a silicon nitride (SiNₓ) film, or the silane for a silicon (Si) film. The second gas flows into the second channels 20 via the second gas supplying means 213, out of the second channels 20 via the second outlets 22, and into the plasma diffusion region 33 between the object 60 and the bottom 32 of the anode 30. The second gas is dissociated and excited by energy transfer from the plasma diffusion region 33 to deposit film 61 on the object 60.

In another embodiment, if the plasma processing apparatus is used in the surface-processing applications such as the etching process, the first and second gases can be selected from sulfur hexafluoride (SF₆), chlorine (Cl₂), nitrogen trifluoride (NF₃), oxygen, and so on.

In the exemplary embodiment as shown in FIGS. 5 and 6, the first channels 11 and the second channels 20 are formed in circular cross-section, and hence each cross-section of the first and second inlets 111 and 21 and the first and second outlets 112 and 22 is round. The first channels 11 and second channels 20 are disposed in a matrix, wherein the first channels 11 alternate with the second channels 20 as shown in FIG. 5, and so are the first outlets 112 and the second outlets 22. Since plasma is created in the multiple first channels 11, the possibility of electron bumping in the multiple first channels 11 can be increased and hence the plasma is intensified. The effect of ion bombardment on the object can also be avoided. Furthermore, since the multiple first channels 11 alternate with the multiple second channels 20, the first and second gases can be uniformly distributed. Meanwhile, since the second gas supplying means 213 is not disposed in the area where the plasma is generated, the deposits at the outlet of the gas supplying means 22 can be prevented as well.

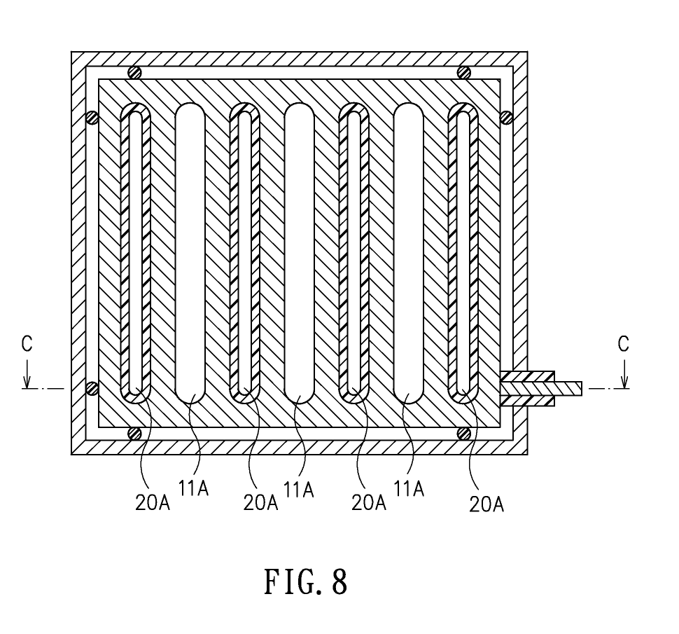

Please refer to FIGS. 7 and 8, which are bottom views of the plasma processing apparatus according to another two embodiments of the present disclosure, based on the same cross-sectional structure as shown in FIG. 6. In FIG. 7, the first and second channels 11 and 20 are disposed in a matrix with alternating columns of the first channels 11 and the second channels 20, and so are the first outlets 112 and the second outlets 22. Thus, FIG. 6 can be a cross-sectional view taken along a line B-B′ of FIG. 7. On the other hand, each cross-section of the first and second channels 11A and 20A and all the terminals can be bar-shaped, as shown in FIG. 8. Then the first and second channels 11A and 20A are disposed in a row with alternating elements of the first channel 11A and the second channel 20A. Thus, FIG. 6 can be a cross-sectional view taken along a line C-C′ of FIG. 8.

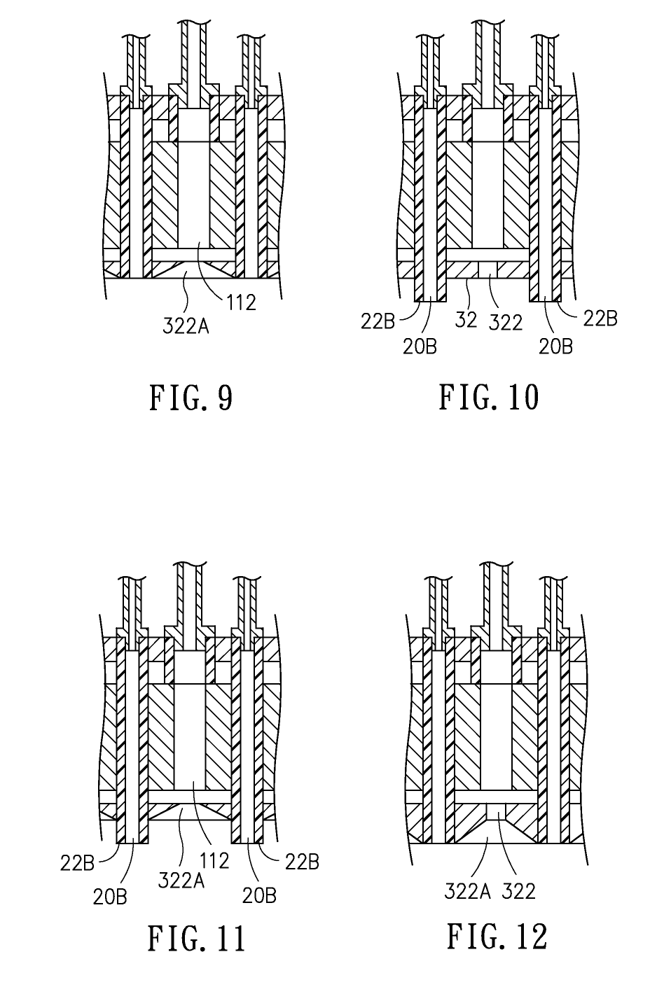

For further improvement of the plasma distribution in the plasma diffusion region 33, various structures of the plasma outlet 322 and the second channels 20 are provided in the following embodiments. As shown in FIG. 9, the plasma outlet 322A can be formed in the shape of diffuser, which is narrower at the end close to the first outlet 112 than the other end. The shape of the plasma outlet 322A leads the generated plasma in the first channel 11 to be output in a more uniform distribution. In FIG. 10, the second outlets 22B of the second channels 20B can be extended beyond the lower end of the plasma outlet 322, so as to avoid the ionization of the second gas and hence to alleviate the problem of film deposition in the opening of the anode. The embodiment in FIG. 11 combines the features of the foregoing embodiments in FIGS. 9 and 10. The plasma outlet 322A is formed in the shape of a diffuser which is narrower at the upper end than at the lower end, while the second outlets 22B are extended beyond the lower end of the plasma outlet 322A. Furthermore, in the embodiment of FIG. 12, the first and second outlets 112 and 22 are extended beyond their lower end in FIG. 9, while the plasma outlet 322A is formed in the shape of diffuser with its upper end connected to the lower end of the extended outlets.

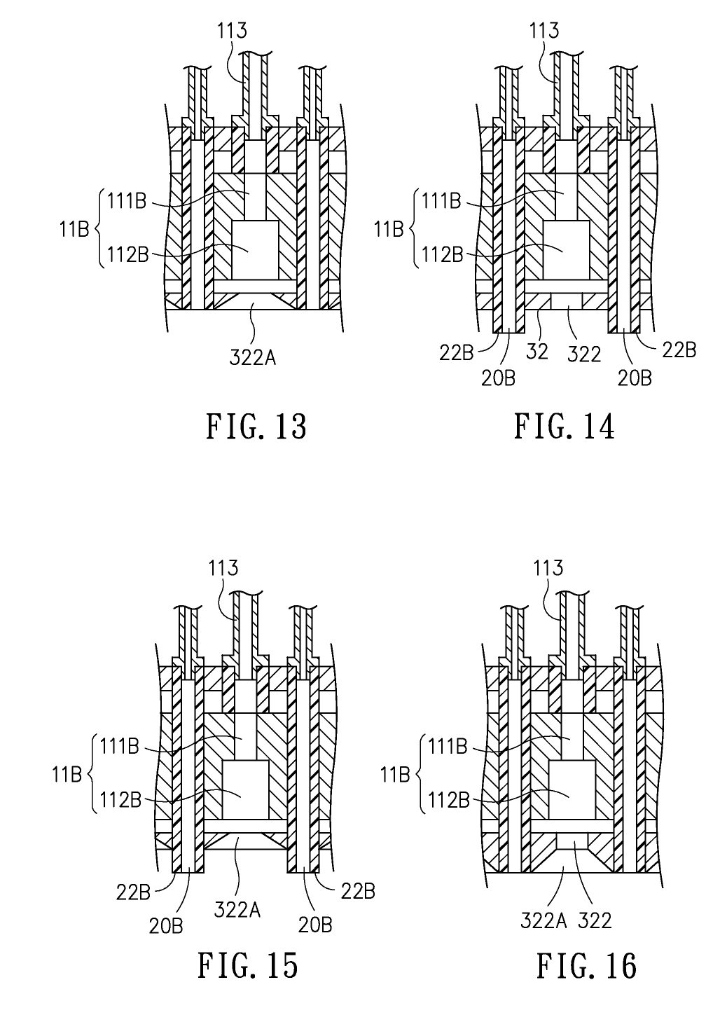

For further enhancement of the plasma ionization in the first channels 11 and prevention of the plasma feedback to the first gas supplying means 113, a stepped structure 11B can be designed so that each first channel 11 is composed of a first part 111B and a second part 112B connected in series, as shown in FIGS. 13 to 16, wherein the second part 112B in the lower stepped part of the first channel 11 is wider and closer to the plasma outlet 322/322A of the anode 30 than the first part 111B in the upper stepped part. FIGS. 13 to 16 show the embodiments which combine this feature of the stepped structure with the channel structure as shown in FIGS. 9 to 12, respectively.

In one embodiment, the insulators are disposed between the anode and the discrete cathode chambers to form multiple gas supplying means to deliver the second gas, so that the second gas can be distributed uniformly in the plasma region without an additional device outside the anode. The embodiments according to the present disclosure may have advantages of large-scale processing, uniform plasma distribution, and high plasma ionization to lower the production cost and to improve the film quality for the applications of large-area film deposition.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A plasma processing apparatus comprising:
a cathode module comprising a plurality of first channels which generate plasma;
an anode having a chamber which contains the cathode and having at least one plasma outlet corresponding to the first channels;
an electrode connected to a high-frequency electrical power and the cathode; and
a plurality of second channels penetrating through the anode;
wherein each first channel and each second channel are disposed alternately.

2. The plasma processing apparatus of claim 1, wherein each first channel comprises a first inlet and a first outlet, a first gas provided into the first channels via the first inlets, and the generated plasma expelled out of the first channels via the first outlets.

3. The plasma processing apparatus of claim 2, wherein each second channel comprises a second inlet and a second outlet, a second gas provided into the second channels via the second inlets, and the second gas expelled out of the second channels via the second outlets.

4. The plasma processing apparatus of claim 3, wherein each cross-section of the first and second inlets and the first and second outlets is round.

5. The plasma processing apparatus of claim 3, wherein each first outlet and each second outlet are disposed alternately.

6. The plasma processing apparatus of claim 3, wherein the first and second outlets are disposed in a matrix with alternating columns of the first outlets and the second outlets.

7. The plasma processing apparatus of claim 3, wherein each cross-section of the first and second inlets and the first and second outlets is bar-shaped.

8. The plasma processing apparatus of claim 7, wherein the first and second outlets are disposed in a row with alternating elements of the first outlet and the second outlet.

9. The plasma processing apparatus of claim 1, wherein the plasma outlet is formed in a shape of diffuser which is narrower at the end close to the first outlet than the other end.

10. The plasma processing apparatus of claim 1, wherein the first channels are formed in a stepped structure which comprises a first part and a second part, wherein the second part is wider and closer to the plasma outlet of the anode than the first part.

11. The plasma processing apparatus of claim 1, wherein the second channels penetrating through the cathode.

12. The plasma processing apparatus of claim 1, wherein the second channels are formed of insulating material.

13. The plasma processing apparatus of claim 1, wherein each second outlet extends beyond the end of the plasma outlet.
